(19) United States
(12) Patent Application Publication
(10) Pub. No.: US 2026/0112999 A1
(43) Pub. Date: Apr. 23, 2026

(54) LSK DEMODULATOR

(71) Applicant: POSTECH RESEARCH AND BUSINESS DEVELOPMENT FOUNDATION, Pohang-si (KR)

(72) Inventors: Jae-Yoon SIM, Pohang-si (KR); Heesung ROH, Pohang-si (KR)

(73) Assignee: POSTECH RESEARCH AND BUSINESS DEVELOPMENT FOUNDATION, Pohang-si (KR)

(21) Appl. No.: 19/277,989

(22) Filed: Jul. 23, 2025

(30) Foreign Application Priority Data
Oct. 23, 2024 (KR) 10-2024-0145987

(51) Int. Cl. H03D 3/00; H03K 3/037

(52) U.S. Cl. CPC H03D 3/00; H03K 3/037

(57) ABSTRACT

Proposed are an LSK demodulator that can implement accurate recovery of a received signal, noise removal, clock synchronization by operating two signal processing means, each of which includes an integrator and a comparator, with a phase difference and a wireless power transmission/sensor information processing device including the LSK demodulator. The LSK demodulator includes an integrating receiver, a quadrature phase clock generator, a finite state machine, a phase interpolator, a duty cycle corrector, and a control circuit.

### CROSS-REFERENCE TO RELATED APPLICATIONS

This application claims the benefit of and priority to Korean Patent Application No. 10-2024-0145987, filed on Oct. 23, 2024, the entire contents of which are incorporated herein by reference for all purposes.

### BACKGROUND

### 1. Technical Field

The present disclosure relates to a wireless power transmission/sensor information processing device, and particularly, to an LSK demodulator that can implement accurate recovery of a received signal, removal of noise included in the signal, clock synchronization by operating two signal processing means, each of which includes an integrator and comparator pair, with a phase difference.

### 2. Related Art

A wearable device, which is directly adhered or implanted onto a skin to detect biometric information such as heart rate, respiration rate, movement, blood pressure, and glucose level, has been continuously developed and used.

FIG. 1 illustrates an example of a wireless power and data transmission system in the related art.

Referring to FIG. 1, a wireless power and data transmission system (hereinafter, referred to as data transmission system) 100 in the related art includes an external device 110 and a wearable device 150.

The external device 110 generates wireless power, transmits the wireless power to the wearable device 150, receives and processes sensor information generated by the wearable device 150.

The wearable device 150 operates a sensor installed therein by using the wireless power received from the external device 110, and transmits sensor information including biometric information from the sensor to the external device 110.

The external device 110 includes a power amplifier (PA) 111, a matching network 112, a first capacitor C1, a first antenna L1, an envelope detector 113, and an amplitude shift keying (ASK) demodulator 114.

The wearable device 150 includes a second antenna L2, a second capacitor C2, a switch 151, a rectifier 152, a power management integrating circuit (PMIC) 153, a sensor readout 154, and a serializer 155.

The first antenna L1 and the second antenna L2 can each be implemented with a coil.

The data transmission system 100 performs transmission/reception of power and transmission/reception of sensor information through the following process.

First, the external device 110 amplifies a signal in the form of a sine wave operating at 433 MHz through the PA 111, and the signal via the PA 111 is transmitted to the first antenna L1 through the matching network 112 and the first capacitor C1. When a distance between the external device 110 and the wearable device 150 is made short, the signal via the PA 111 may be transmitted to the wearable device 150 through magnetic induction of the first antenna L1 and the second antenna L2. Since the signal via the PA 111 is AC, it is converted into DC by the rectifier 152 and then is generated as stable power through the PMIC 153.

The wearable device 150 operates the internal functional blocks through the power generated through the PMIC 153, the sensor readout 154 being one of the internal functional blocks converts the sensor information detected through the sensor (not illustrated) and including the biometric information into a digital signal, and the serializer 155 serializes the sensor information converted by the sensor readout 154.

The switch 151 is turned on or turned off according to a value of the serialized sensor information, the voltage level of V2 of the second antenna L2 is changed according to the state of the switch 151, and the magnetic induction between the second antenna L2 and the first antenna L1 is affected according to the change in the voltage of V2, so that the voltage level of V1 of the first antenna L1 is determined.

FIG. 2 illustrates the voltage level of V1 according to the state of the sensor information.

The left side of FIG. 2 shows a state in which the intensity of the magnetic induction is strong according to the sensor information, that is, the serialized digital sensor information, and the right side of FIG. 2 shows a state in which the intensity of the magnetic induction is weak.

Referring to the left drawing of FIG. 2, it can be seen that when the intensity of the magnetic induction is strong, a voltage difference ΔV according to data is increased, and it can be seen that referring to the right drawing of FIG. 2, the voltage difference ΔV according to the data is decreased.

The intensity of the magnetic induction is affected by various environment factors such as the size and shape of an antenna and an inter-antenna distance d. In an application field in which the size of an antenna needs to be small, since the intensity of the magnetic induction is inevitably weak, there is a disadvantage that the voltage difference of V1 according to data is inevitably decreased.

The voltage difference ΔV of V1 of the first antenna is a difference of a reflected voltage remaining after 433 MHz being a transmission frequency is removed in the envelope detector 113, and finally the signal is recovered through the ASK demodulator 114.

Since the ASK demodulator 114 in the related art does not amplify a signal to be recovered and remove noise at the same time, there is a disadvantage that the two tasks need to be separately performed.

In particular, there is a disadvantage that the ASK demodulator 114 also needs to perform a task for synchronizing a recovered signal with a master clock to be used in a post-processing process.

### SUMMARY

Various embodiments are directed to providing an LSK demodulator that can implement accurate recovery of a received signal, noise removal, clock synchronization by operating two pairs of integrators and comparators with a phase difference, respectively.

In order to solve the above technical problem, an LSK demodulator according to the present disclosure includes an integrating receiver, a quadrature phase clock generator, a finite state machine, a phase interpolator, a duty cycle corrector, and a control circuit.

The integrating receiver generates a recovery data signa by processing an input signal in response to an in-phase signal and a quadrature signal having a phase difference of 90° therebetween, and generates an up signal and a down signal by combining internally generated signals. The quadrature phase clock generator generates the in-phase signal and the quadrature signal having a phase difference of 90° therebetween by processing externally applied signals. The finite state machine outputs a state value in response to the up signal and the down signal. The phase interpolator generates an error proportional signal proportional to an error value of the in-phase signal and the quadrature signal in response to the state value. The duty cycle corrector corrects a duty cycle of the error proportional signal. The control circuit generates the in-phase signal and the quadrature signal by using a signal output from the duty cycle corrector.

The LSK demodulator according to the present disclosure as described above and a wireless power transmission/sensor information processing device including the LSK demodulator have an advantage capable of effectively detecting and recovering a received signal even when wireless data communication is not easily performed because the size of an antenna is small or an inter-antenna distance is long, and thus can be effectively used in biomedical system fields such as smart contact lens systems.

Effects achievable in the disclosure are not limited to the aforementioned effects and the other unmentioned effects will be clearly understood by those skilled in the art from the following description.

### BRIEF DESCRIPTION OF THE DRAWINGS

FIG. 1 illustrates an example of a wireless power and data transmission system in the related art.

FIG. 2 illustrates the voltage level of V1 according to the state of sensor information.

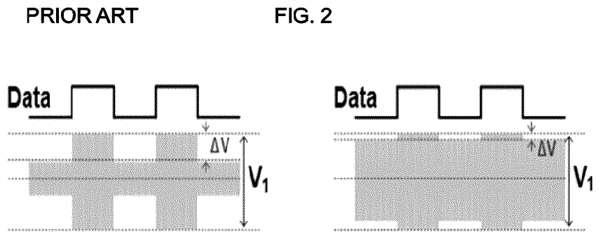

FIG. 3 illustrates an embodiment of a wireless power transmission/sensor information processing device according to the present disclosure.

FIG. 4 is an embodiment of an integrating receiver.

FIG. 5 illustrates a timing diagram of an output signal of an integrator according to the cycle of a clock signal and the cycle of data.

FIG. 6 illustrates a comparison of input/output results between an LSK demodulator of the present disclosure and an LSK demodulator in the related art.

### DETAILED DESCRIPTION

In order to fully understand the present disclosure, advantages in operation of the present disclosure, and objects achieved by carrying out the present disclosure, the accompanying drawings for explaining embodiments of the present disclosure and the contents described in the accompanying drawings need to be referred to.

Hereinafter, the present disclosure is described in detail by describing preferred embodiments of the present disclosure with reference to the accompanying drawings. The same reference numerals presented in each drawing indicate the same components.

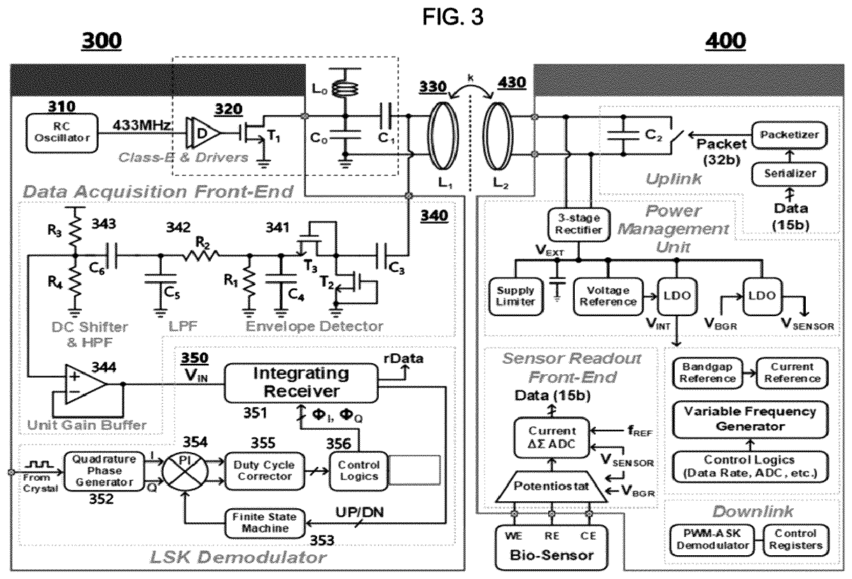

FIG. 3 illustrates an embodiment of a wireless power transmission/sensor information processing device 300 according to the present disclosure.

Referring to FIG. 3, the wireless power transmission/sensor information processing device 300 according to the present disclosure includes an RC oscillator 310, an amplifier 320, a first transmitting and receiving module 330, a data acquisition unit 340, a load shift keying (LSK) demodulator 350.

The RC oscillator 310 generates, for example, an AC signal of 433 MHz. According to an embodiment, the RC oscillator 310 can generate the AC signal of 433 MHz by using a resistor R and a capacitor C.

The amplifier (320) includes a driver (D) that buffers the AC signal received from the oscillator (310), an output transistor (T1) that amplifies the buffered signal from the driver, an inductor (L0), and two capacitors (C0 and C1).

The amplifier 320 preferably uses a class-E and an internal configuration of the amplifier 320 can be variously implemented and is not limited to the components illustrated in FIG. 3.

The first transmitting and receiving module 330 transmits the AC signal output from the amplifier 320 to a wearable device 400, and receives a signal transmitted from a second transmitting and receiving module 430 of the wearable device 400. That is, the first transmitting and receiving module 330 and the second transmitting and receiving module 430 are counterparts that transmit and receive different signals.

The RC oscillator 310, the amplifier 320, and the first transmitting and receiving module 330 are functional blocks activated when the wireless power transmission/sensor information processing device 300 supplies power to the wearable device 400, and the first transmitting and receiving module 330, the data acquisition unit 340, and the LSK demodulator 350 are functional blocks that process a signal received from the wearable device 400.

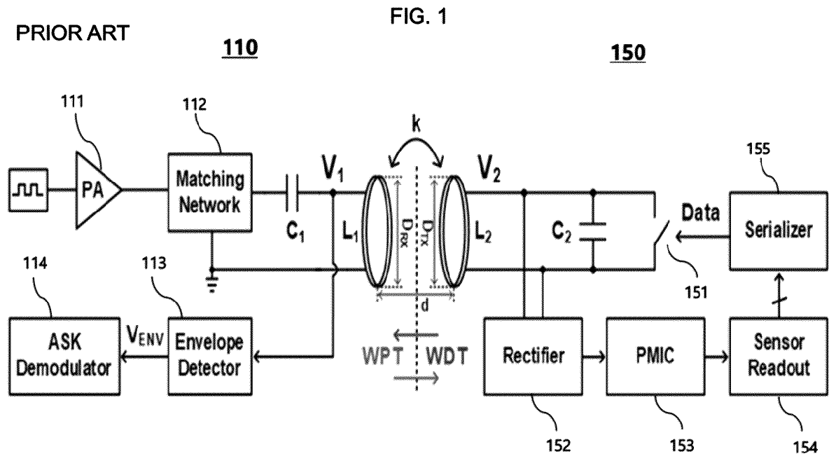

Since the wearable device 400 illustrated in FIG. 3 is, for example, an implantable medical device and is means corresponding to the wearable device 150 illustrated in FIG. 1, a detailed description thereof is omitted.

The transmission/reception of power using the magnetic induction phenomenon of an inductor L₁ constituting the first transmitting and receiving module 330 and an inductor L₂ constituting the second transmitting and receiving module 430 has been described above.

The data acquisition unit 340 processes the sensor information (hereinafter, a sensor signal) received through the first transmitting and receiving module 330, and includes an envelope detector 341, a low-pass filter (LPF) 342, a DC shifter & high-pass filter (HPF) 343, and a unit gain buffer 344. The sensor information includes biometric information on a wearer of the wearable device 400.

The envelope detector 341 detects an envelope of the sensor signal received via the first transmitting and receiving module 330, by using two capacitors C₃ and C₄, two transistors T₁ and T₂, and one resistor R₁. The envelope detector 341 detects a voltage difference of the received sensor signal.

The numbers added to the capacitor and the resistor being passive elements and a transistor being an active element may be used to distinguish the elements, and for example, C₃ may denote a third capacitor, R₁ may denote a first resistor, and T₁ may denote a first transistor. This description applies equally to the entire content of the present disclosure. However, except for when referring to specific elements, they are briefly described as capacitors, resistors, and transistors.

The LPF 342 allows a low frequency component of the sensor signal having passed through the envelope detector 341 to selectively pass therethrough by using a resistor R₂ and a capacitor C₅.

The DC shifter & HPF 343 allows a high frequency component of the sensor signal having passed through the LPF 342 to selectively pass therethrough by using one capacitor C₆ and two resistors R₃ and R₄ and simultaneously shifts a DC value to a desired value.

The unit gain buffer 344 improves the driving capability of the sensor signal having passed through the DC shifter & HPF 343.

The functional components 341 to 344 of the data acquisition unit 340 are not functional blocks constituting the core idea of the present disclosure, but have been briefly described above in order to facilitate the understanding of the operation of the wireless power transmission/sensor information processing device 300 according to the present disclosure.

The LSK demodulator 350 can implement accurate recovery of a received sensor signal, noise removal, and clock synchronization by separately operating two signal processing means, each of which includes an integrator and comparator pair, with a phase difference of 90°, and to this end, includes an integrating receiver 351, a quadrature phase clock generator 352, a finite state machine 353, a phase interpolator 354, a duty cycle corrector 355, and a control logics 356.

The integrating receiver 351 generates a recovery data signa rData that implements accurate recovery of a signal V_{IN} output from the unit gain buffer 344, noise removal, and clock synchronization, and an up signal UP and a down signal DN used for controlling the state of the finite state machine 353.

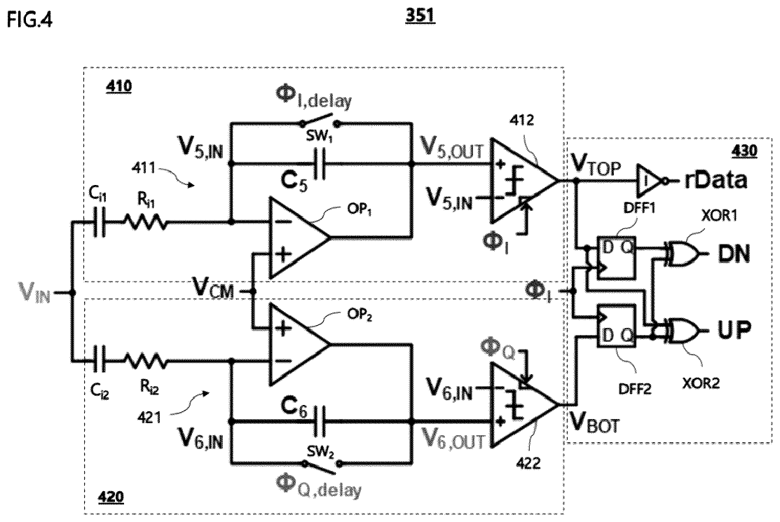

FIG. 4 is an embodiment of the integrating receiver 351.

Referring to FIG. 4, the integrating receiver 351 includes two signal processing means 410 and 420 and a logic circuit 430.

A first integrator 411 and a first comparator 412 form a pair to constitute a first signal processing means 410 and a second integrator 421 and a second comparator 422 form a pair to constitute a second signal processing means 420.

The first signal processing means 410 is first described.

The first signal processing means 410 includes the first integrator 411 and the first comparator 412, and operates in response to an in-phase signal Φ_{I} of two clock signals In-phase signal Φ_{I} and Quadrature signal Φ_{Q} having a phase difference of 90° therebetween, and a delayed in-phase signal Φ_{I,delay} delay obtained by delaying the in-phase signal Φ_{I} by a predetermined time. For example, the first integrator 411 performs integration in response to the delayed in-phase signal Φ_{I,delay} delay and the first comparator 412 operates in response to the in-phase signal Φ_{I}.

The second signal processing means 420 includes the second integrator 421 and the second comparator 422, and operates in response to the quadrature signal Φ_{Q} having a phase difference of 90° from the in-phase signal Φ_{I} used by the first signal processing means 410 and a delayed quadrature signal Φ_{Q,delay} delay obtained by delaying a phase of the quadrature signal Φ_{Q} by a predetermined time. For example, the second integrator 421 performs integration in response to the delayed quadrature signal Φ_{Q,delay} delay and the second comparator 422 operates in response to the quadrature signal Φ_{Q}.

The first integrator 411 includes a first input capacitor Cᵢ₁, a first input resistor Rᵢ₁, a first feedback capacitor C₅, a first feedback switch SW₁, and a first amplifier OP₁.

The first input capacitor Cᵢ₁ receives the signal V_{IN} output from the unit gain buffer 344 through one terminal thereof.

The first input resistor Rᵢ₁ has one terminal connected to the other terminal of the first input capacitor Cᵢ₁, and the other terminal connected to a negative input terminal − of the first amplifier OP₁.

Both terminals of the fifth feedback capacitor C₅ are connected to the negative input terminal − and an output terminal of the first amplifier OP₁.

The first feedback switch SW₁ switches between the negative input terminal − and the output terminal of the first amplifier OP₁ in response to the delayed in-phase signal Φ_{I,delay} delay.

A common voltage VCM is applied to a positive input terminal + of the first amplifier OP₁.

For convenience of description, when a voltage dropped to the negative input terminal − of the first amplifier OP₁ is V_{5,IN}, a voltage dropped to the output terminal of the first amplifier OP₁ is assumed to be V_{5,OUT}.

The first comparator 412 can be implemented as a comparator that operates in response to the in-phase signal Φ_{I}, and has a positive input terminal + to which the output terminal of the first amplifier OP₁ is connected and a negative input terminal − to which the negative input terminal − of the first amplifier OP₁ is connected. That is, the first comparator 412 generates a result V_{TOP} obtained by comparing the voltage level V_{5,OUT} of the output terminal of the first amplifier OP₁ and the voltage level V_{5,IN} of the negative input terminal − of the first amplifier OP₁.

The second integrator 421 includes a second input capacitor Cᵢ₂ a second input resistor Rᵢ₂, a second feedback capacitor C₆, a second feedback switch SW₂, and a second amplifier OP₂.

The second comparator 422 can be implemented as a comparator that operates in response to the quadrature signal Φ_{Q}, and has a positive input terminal + to which an output terminal of the second amplifier OP₂ is connected and a negative input terminal − to which a negative input terminal − of the second amplifier OP₂ is connected.

Since the second integrator 421 is identical to the first integrator 411 in terms of the components and the connection relationship thereof, a detailed description thereof is omitted. However, the second integrator 421 is different from the first integrator 411 in that the second feedback switch SW₂ operates in response to the delayed quadrature signal Φ_{Q,delay} delay and the second comparator 422 operates in response to the quadrature signal Φ_{Q}.

The second comparator 422 generates a result V_{BOT} obtained by comparing a voltage level V_{6,OUT} of the output terminal of the second amplifier OP₂ and a voltage level V_{6,IN} of the negative input terminal − of the second amplifier OP₂.

The logic circuit 430 includes a first inverter I, a first D flip-flop DFF1, a second D flip-flop DFF2, a first exclusive OR circuit XOR1, and a second exclusive OR circuit XOR2.

The first inverter I generates the recovery data signal rData by inverting the phase of the output voltage V_{TOP} of the first comparator 412.

The first D flip-flop DFF1 delays the output voltage V_{TOP} of the first comparator 412 in accordance with the cycle of the in-phase signal Φ_{I}.

The second D flip-flop DFF2 delays the output voltage V_{BOT} of the second comparator 422 in accordance with the cycle of the in-phase signal Φ_{I}.

The first exclusive OR circuit XOR1 generates the down signal DOWN by exclusively ORing an output signal of the first D flip-flop DFF1 and an output signal of the second D flip-flop DFF2.

The second exclusive OR circuit XOR2 generates the up signal UP by exclusively ORing the output voltage V_{TOP} of the first comparator 412 and the output signal of the second D flip-flop DFF2.

The following description is given with reference to FIG. 3.

The quadrature phase clock generator 352 generates an in-phase signal I and a quadrature signal Q having a phase difference of 90° therebetween by using a signal received from a crystal oscillator (not illustrated).

The finite state machine 353 outputs a selected state value in response to the down signal DN and the up signal UP generated by the integrating receiver 351. Since the configuration and operation of the finite state machine 353 are techniques easily understandable by those skilled in the art, a detailed description thereof is omitted.

The phase interpolator 354 generates a signal proportional to a current error value of the in-phase signal I and the quadrature signal Q output from the quadrature phase clock generator 352, in correspondence to the state value received from the finite state machine 353.

The duty cycle corrector 355 corrects the duty cycle of the signal output from the phase interpolator 354.

The control logics 356 generates the in-phase signal Φ_{I} and the quadrature signal Φ_{Q} by using the signal output from the duty cycle corrector 355.

A sensor information processing process of the wireless power transmission/sensor information processing device 300 according to the present disclosure is described with reference to FIGS. 3 and 4.

First, when the in-phase signal Φ_{I} being an in-phase clock signal is activated, the first feedback switch SW₁ included in the first integrator 411 is short-circuited and both ends of the first feedback capacitor C₅ are initialized (or reset) to have a voltage level identical to that of the common voltage V_{CM}.

Through the initialization process, an offset voltage of the first amplifier OP₁ connected to the first feedback capacitor C₅ for feedback and the common voltage V_{CM} are added and stored at both ends of the first feedback capacitor C₅.

After the initialization process, when the first feedback switch SW₁ is opened, the first integrator 411 receives the signal V_{IN} output from the unit gain buffer 344 constituting the data acquisition unit 340 and performs integration during the cycle of data. The data is data corresponding to the sensor information and may be another expression of the signal V_{IN}.

The value of the signal V_{IN} is formed to be identical to, greater than, or smaller than the value of the common voltage V_{CM} being a reset voltage, and accordingly, the first integrator 411 integrates a difference value between the signal V_{IN} and the common voltage V_{CM}.

The second integrator 421 operates in the same manner as the first integrator 411, but is different from the first integrator 411 in that a signal having a phase difference of 90° from the clock signal used in the operation of the first integrator 411 is used. Accordingly, the operation of the second integrator 421 is replaced with the description for the operation of the first integrator 411 described above.

When the cycles of the clock signals Φ_{I} and Φ_{Q} used for integration are compared with the cycle of the data, it can be classified into cases where the clock signals ΦI and ΦQ lag behind, are aligned with, or lead the data timing.

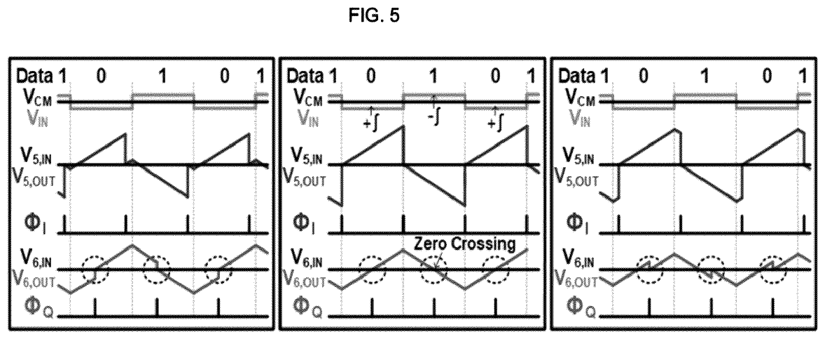

FIG. 5 illustrates a timing diagram of the output signal of the integrator according to the cycle of the clock signal and the cycle of the data.

The timing diagrams on the left, center, and right of FIG. 5 represent states in which the clock signal leads, is aligned with, or lags behind the timing of the data, respectively.

First, the timing diagram illustrated in the center of FIG. 5 is described.

The first integrator 411 is reset so that V_{5,IN} and V_{5,OUT}, which are the voltage values of the left terminal and the right terminal of the first feedback capacitor C₅, are the same as the common voltage V_{CM} in a phase I (Φ_{I}). After the reset, when the data is zero, the voltage V_{IN} is smaller than the common voltage V_{CM} and the first integrator 411 performs positive integration. In such a case, the value of V_{5,OUT} being the operation result of the first integrator 411 increases during the cycle of the data.

During the integration process performed by the first integrator 411, the signal is amplified and an influence by noise is reduced. A process, in which at the end of the cycle of the data, the result V_{TOP} obtained by comparing the value of V_{5,OUT} and the value of V_{5,IN} of the first integrator 411 by the first comparator 412 is stored and the value of V_{5,IN} and the value of V_{5,OUT} are reset and integrated again in the phase Φ_{I}, is repeated during the cycle of the data.

Since the second integrator 421 operates in response to the quadrature signal Φ_{Q} having a phase difference of 90° from the first integrator 411, referring to the timing diagram illustrated in the center of FIG. 5, it can be seen that the value of V_{6,OUT} has a phase difference of 90° from the value of V_{5,OUT}. A process, in which in a phase Q (Φ_{Q}) having a phase difference of 90° from the phase I (Φ_{I}), the result V_{BOT} obtained by comparing the value of V_{6,OUT} and the value of V_{6,IN} of the second integrator 421 by the second comparator 422 is stored and the value of V_{6,IN} and the value of V_{6,OUT} are reset and integrated again in the phase Φ_{Q}, is repeated during the cycle of the data.

Referring to the timing diagram illustrated in the center of FIG. 5, it can be seen that the reset time point of the output voltage V5,OUT of the first integrator 411 is aligned with the transition point, i.e., the start of the data Data1 or Data0, and the output voltage V6,OUT of the second integrator 421 exactly zero-crosses at the point corresponding to 90° after the start of the data.

Referring to the timing diagram illustrated on the left of FIG. 5, when the clock phases ΦI and ΦQ lead the data timing, the activation time point of phase I (ΦI) occurs before the start of the data (i.e., the transition point of Data1), and the activation time point of phase Q (ΦQ) occurs before the point corresponding to 90° after the data start. As a result, the output voltage waveforms V5,OUT of the first integrator 411 and V6,OUT of the second integrator 421 differ from those shown in the center timing diagram of FIG. 5.

Similarly, referring to the timing diagram illustrated on the right of FIG. 5, when the clock phases ΦI and ΦQ lag behind the data timing, the activation time point of phase I (ΦI) occurs after a delay from the data start (i.e., after the transition point of Data1), and the activation time point of phase Q (ΦQ) occurs after the point corresponding to 90° from the data start. Consequently, the output voltage waveforms V5,OUT of the first integrator 411 and V6,OUT of the second integrator 421 also differ from those in the center timing diagram of FIG. 5.

The final target of the present disclosure is the timing diagram illustrated in the center of FIG. 5.

The previous result V_{TOP} of the first comparator 412 and the previous result V_{BOT} of the second comparator 422 stored in the two D flip-flops DFF1 and DFF2, respectively, are subjected to an exclusive OR operation XOR1 to determine a down signal DN, and the current result V_{TOP} of the first comparator 412 and the previous result V_{BOT} of the second comparator 422 are subjected to an exclusive OR operation XOR2 to determine an up signal UP. The current result V_{TOP} of the first comparator 412 means an operation result according to a clock signal corrected by the previously determined down signal DN and up signal UP.

The values of the up signal UP and the down signal DN are determined according to when the cycle of a clock signal is higher than the cycle of data and when the cycle of the clock signal is lower than the cycle of the data. As described above, the up signal UP and the down signal DN are used to adjust the cycles of the two clock signals Φ_{I} and Φ_{Q}.

In the case of the timing diagram illustrated in the center of FIG. 5, the phase I(Φ_{I}) is synchronized with the data rData and the phase Q(Φ_{Q}) is synchronized with a master clock rClk.

In the case of the timing diagram illustrated on the left of FIG. 5, the up signal UP is activated to change the phase of the signal of the phase I(Φ_{I}) and the signal of the phase Q(Φ_{Q}).

In the case of the timing diagram illustrated on the right of FIG. 5, the down signal DN is activated to change the phase of the signal of the phase I(Φ_{I}) and the signal of the phase Q(Φ_{Q}).

Referring to the timing diagram illustrated in the center of FIG. 5 in which the correction has been finally completed through the data integration and comparison process, the generation process of the up signal UP and the down signal DN, and the process of correcting the cycle of the clock signal by using the up signal UP and the down signal DN, the phase Q(Φ_{Q}) is located at the exact center of the data Data1 and can be used as a clock for recovered data.

Accordingly, when the phase Q(Φ_{Q}) is used as the master clock rClk synchronized with the recovered data, a signal to be recovered through the two integrators 411 and 421 operating with the two clock signals Φ_{I} and Φ_{Q} having a difference of 90° therebetween is amplified and noise included in the signal to be recovered is cancelled, so that data can be accurately recovered even in a situation where the amplitude of a signal received wirelessly is small.

The present disclosure can implement clock synchronization together with accurate data recovery by operating the two integrators 411 and 421 and the two comparators 412 and 422 with a phase difference of 90°.

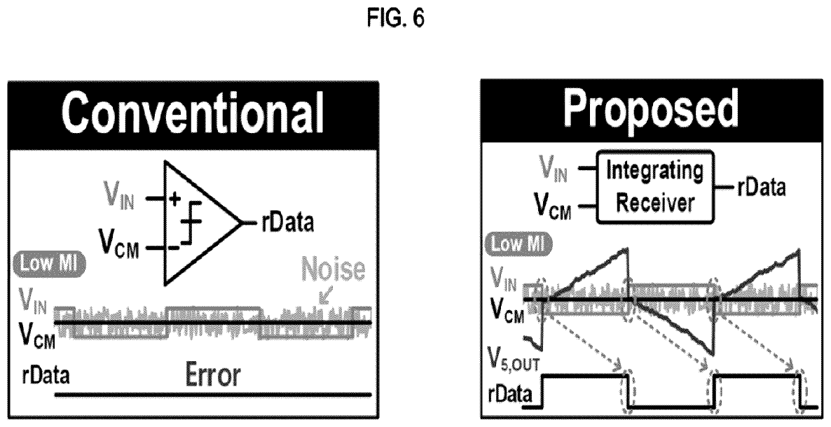

FIG. 6 illustrates a comparison of input/output results between the LSK demodulator of the present disclosure and the LSK demodulator in the related art.

The structure of the LSK demodulator in the related art illustrated on the left of FIG. 6 is simple, but has a disadvantage that accurately recovering (rData) the input signal V_{IN} is difficult when a modulation index indicating the degree of modulation is small enough to be affected by noise or even a small amount of offset exists in a comparator. That is, when the wireless power transmission/sensor information processing device 300 and the wearable device 400 are in a close distance, a signal can be accurately recovered to some extent, but when the wireless power transmission/sensor information processing device 300 and the wearable device 400 are in a far distance, since a signal to noise ratio (SNR) is reduced, there is a disadvantage that recovery (rData) of a signal is not complete.

However, the LSK demodulator of the present disclosure illustrated on the right of FIG. 6 is different from the related art in that the input signal V_{IN} is not directly applied to a comparator, a signal is integrated over a data period, and then a comparison is performed, so that a signal to noise ratio (SNR) is increased and thus data can be effectively recovered (rData) even in a situation where a modulation index is low.

The above technical idea of the present disclosure has been described with the accompanying drawings, but this is an example of a preferred embodiment of the present disclosure and does not limit the present disclosure. In addition, it is clear that any skilled in the art to which the present disclosure pertains can make various modifications and imitations without deviating from the scope of the technical idea of the present disclosure.

What is claimed is:

1. An LSK demodulator comprising:
a clock generation unit configured to generate a first clock signal and a second clock signal having the same frequency and having a phase difference of 90° therebetween by using a reference clock signal (from crystal) applied from an outside, an up signal, and a down signal;
a data recovery unit configured to generate data recovery signals by processing an input signal according to the first clock signal and the second clock signal; and
a phase correction unit configured to correct a phase so that a portion of the second clock signal to be activated is located at a center of a data period by using the first clock signal and the data recovery signals.

2. The LSK demodulator of claim 1, wherein the data recovery unit comprises:
a first signal processing means including a first integrator configured to integrate the input signal according to the first clock signal and a first comparator configured to generate a first data recovery signal being one of the data recovery signals based on an output polarity of the first integrator; and
a second signal processing means including a second integrator configured to integrate the input signal according to the second clock signal and a second comparator configured to generate a second data recovery signal being another one of the data recovery signals based on an output polarity of the second integrator.

3. The LSK demodulator of claim 2, wherein the phase correction unit generates a recovery data signal corresponding to the first data recovery signal, and
generates an up signal and a down signal based on a phase error detected by comparing the first data recovery signal and the second data recovery signal according to the first clock signal.

4. The LSK demodulator of claim 3, wherein the phase correction unit controls a phase interpolator constituting the clock generation unit according to the up signal and the down signal, thereby correcting phases of the first clock signal and the second clock signal.

5. The LSK demodulator of claim 1, wherein the clock generation unit comprises:
a quadrature phase clock generator configured to receive the reference clock signal (from crystal) to generate a first reference clock signal and a second reference clock signal having a phase difference of 90° therebetween,
wherein the first reference clock signal and the second reference clock signal are used to generate the first clock signal and the second clock signal together with the up signal and the down signal.

6. The LSK demodulator of claim 5, wherein the clock generation unit further comprises:
a phase interpolator configured to generate a signal that reflects a phase error of the first reference clock signal and the second reference clock signal based on a cumulative difference between the up signal and the down signal,
wherein phases of the first clock signal and the second clock signal are dynamically corrected by using an output of the phase interpolator.
